(19) United States
(12) Patent Application Publication
(10) Pub. No.: US 2010/0144148 A1
(43) Pub. Date: Jun. 10, 2010

(54) METHOD FOR MANUFACTURE OF SEMICONDUCTOR DEVICE

(76) Inventors: Kazuya Fukuhara, Tokyo (JP); Satoshi Nagai, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/613,213

(22) Filed: Nov. 5, 2009

(30) Foreign Application Priority Data
Nov. 7, 2008 (JP) 2008-286544

(51) Int. Cl. H01L 21/308; G06F 17/50

(52) U.S. Cl. 438/689; 716/21; 257/E21.235

(57) ABSTRACT

A semiconductor device manufacturing method includes designing a resist structure including a film having antireflection function for exposure light and a resist on the film to be formed on a substrate, designing an exposure condition of the resist obtained by exposing and developing the resist such that a resist pattern is finished as designed, obtaining criteria value for estimating influence of a resist pattern upon a dimension or shape of a device pattern, the resist pattern being obtained by exposing the resist under the designed exposure condition and developing the exposed resist, the device pattern being obtained by etching the resist structure using the resist pattern as a mask, determining whether the designed exposure condition is acceptable or not based on the criteria value, and redesigning the exposure condition of the resist without changing the designed resist structure when the designed exposure condition is determined not acceptable.

### CROSS-REFERENCE TO RELATED APPLICATIONS

This application is based upon and claims the benefit of priority from prior Japanese Patent Application No. 2008-286544, filed Nov. 7, 2008, the entire contents of which are incorporated herein by reference.

### BACKGROUND OF THE INVENTION

1. Field of the Invention

The present invention relates to a method for manufacture of a semiconductor device using a resist structure including an anti-reflective coating and a resist formed on it.

2. Description of the Related Art

A method is known for shaping a resist pattern by providing an anti-reflective film between the resist and a substrate to be processed in order to suppress light reflection from beneath the resist at the time of exposure (C. Mack, Microlithography World February 2003).

With the recent miniaturization of device patterns, the numerical aperture (NA) of an exposure apparatus has increased (increasing of NA). Due to the such increasing of NA, the resist is exposed by using the light in a wide range of incident angles from perpendicular light to oblique light (about 70 degrees). Under such circumstances, a proposal has been made for using an anti-reflective film having an appropriate antireflective effect (Japanese Patent No. 3468226, Matsuzawa, J. Photopolymer Science and Technology, 18, 2005, pp. 587-592).

Next, an example of processing method for a substrate to be processed, which is called a hard mask process, will be explained.

In this processing method, first, a bottom film, an intermediate film and a resist are formed in sequence on the substrate. The bottom film, the intermediate film and the resist constitute a resist stack.

Next, a resist pattern of the resist is formed by performing exposure and development. At this time, the intermediate film functions as the anti-reflective film. Depending on circumstances, the bottom film also serves as the anti-reflective film at the time of exposure.

Next, the intermediate film is etched using the resist pattern as a mask.

Next, the bottom film is etched by using the resist pattern and the intermediate film as a mask. The resist pattern disappears during the etching of the bottom film.

However, this type of processing method has the following problems.

As described above, the intermediate film is required to function as the anti-reflective film during the exposure step, and depending on circumstances, it is required that the bottom film also function as the anti-reflective film. In the description which follows, a single layer film of the intermediate film or a stacked layer film of the intermediate film and the bottom film is generically referred to as an underlying film.

On the other hand, in the etching step, the underlying film is required to have desired characteristics as an etching mask (etching selectivity, stability of sidewall shape, etc.). However, it takes time to find materials of the underlying film that satisfy the characteristics of both the anti-resistive film and the etching mask, in addition, the film materials that satisfy both the characteristics cannot necessarily be used. As a result, there arises a problem that it takes long to start up the semiconductor process.

In addition, the desired anti-reflection characteristic may be obtained in some cases by adding at least one film for adjusting reflection characteristic (adjusting film) between the intermediate film and the resist or between the bottom film and the intermediate film. However, this method is not appropriate for manufacturing the semiconductor devices since the characteristics of the adjusting film as the etching mask must be considered and the addition of the adjust film results in rising the cost of manufacturing the semiconductor devices.

### BRIEF SUMMARY OF THE INVENTION

According to an aspect of the present invention, there is provided a method for manufacturing a semiconductor device comprising: designing a resist structure to be formed on a substrate, the resist structure comprising a film having antireflection function for exposure light and a resist provide on the film; designing an exposure condition of the resist such that a resist pattern is finished as designed, the resist pattern being obtained by exposing and developing the resist; obtaining criteria value for estimating influence of a resist pattern upon a dimension or shape of a device pattern, the resist pattern being obtained by exposing the resist under the designed exposure condition and developing the exposed resist, the device pattern being obtained by etching the resist structure by using the resist pattern as a mask; determining whether the designed exposure condition is acceptable or not based on the criteria value; and redesigning the exposure condition of the resist without changing the designed resist structure when the designed exposure condition is determined not acceptable.

### BRIEF DESCRIPTION OF THE SEVERAL VIEWS OF THE DRAWING

FIG. 1 is a flowchart illustrating a method for manufacturing a semiconductor device according to a first embodiment;

FIG. 2 is a flowchart illustrating the method for manufacturing the semiconductor device according to the first embodiment following FIG. 1;

FIGS. 3A to 3C illustrate an example of relationship between secondary light source shape and cross-sectional shape of resist pattern (narrowed part CD value);

FIG. 4 is a flowchart illustrating a method for manufacturing a semiconductor device according to a modification of the first embodiment;

FIG. 5 is a flowchart illustrating a method for manufacturing a semiconductor device according to a second embodiment;

FIGS. 6A to 6C illustrate an example of relationship between state of polarization of exposure light (degree of polarization) and cross-sectional shape of the resist pattern (CD value of narrowed part);

FIG. 7 is a flowchart illustrating a method for manufacturing a semiconductor device according to a fourth embodiment;

FIG. 8 is a schematic diagram of an exposure apparatus according to a sixth embodiment;

FIGS. 9A and 9B are diagrams for explaining attitude control of polarizer;

FIG. 10 is a schematic view illustrating an exposure apparatus according to a seventh embodiment; and

FIG. 11 is a flowchart illustrating a method for manufacturing a semiconductor device according to a ninth embodiment.

### DETAILED DESCRIPTION OF THE INVENTION

The embodiments will be described hereinafter with reference to the accompanying drawings.

### First Embodiment

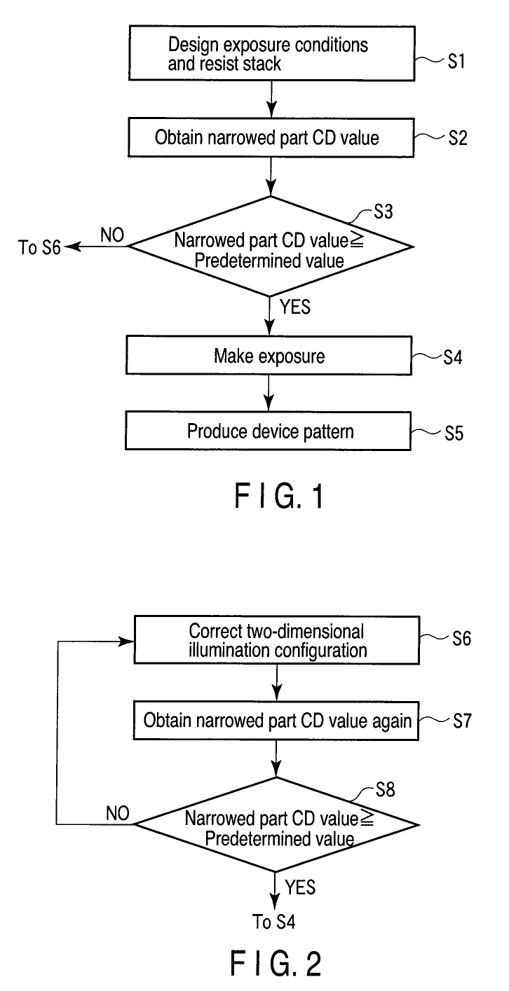

FIGS. 1 and 2 are flowcharts illustrating a method for manufacturing a semiconductor device according to a first embodiment.

[Step S1]

The exposure conditions are designed using a well-known method. Based on this designed exposure conditions and etching characteristics, a structure including a resist and its underlying film is designed using a well-known method. Examples of underlying films are a single layer film of an intermediate film alone, a stacked layer film of bottom/intermediate films, a stacked layer film of bottom/middle/anti-reflective films, and a stacked layer film of bottom/anti-reflective/intermediate films.

Further, when it is required to form a film on the resist, the structure is designed including that film. An example of the film to be formed on the resist is a surface protective film to be formed on the resist in immersion exposure. The surface protective film is one for preventing a surface of the resist from being generated water mark or the like thereon when the resist contacts immersion liquid (liquid).

In the description which follows, a structure including the resist and the underlying film, and a structure including the resist, the underlying film, and the film formed on the resist is generically referred to as a resist stack (resist structure). The resist stack is designed so that required anti-reflection characteristics, CD (critical dimension) accuracy and etching characteristics are obtained.

One method to design the anti-reflection performance of the resist stack comprises, for example, designing reflectivities of the resist and the underlying film to be small under the incident angle range used. Another method comprises designing the thickness and optical constant of the each element constituting the resist stack (the resist, the underlying film, the surface protective film) such that the accuracy of CD of the resist pattern has sufficient latitudes to the exposure amount error and focus error by calculating a three-dimensional shape (including dimensions) of a resist pattern to be formed after exposure and development.

[Step S2]

Relating to a resist pattern obtained by exposing and developing the resist of the resist stack, the cross-sectional dimension (width dimension) of the resist pattern at a certain position in the height direction is obtained. The narrowed part CD value may be the value at a position of narrowed part at a specific height of the resist pattern or the value at a position of narrowed part having the smallest dimension in width.

The narrowed part CD value is obtained based on a three-dimensional shape of the resist pattern resist pattern to be obtained by the exposing and developing wherein the three-dimensional shape is predicted by calculation or is obtained by measuring dimensions of a resist pattern which is obtained by actually exposing and developing the resist stack.

If the narrowed part CD value small, the shape or dimensions of the resist pattern is disturbed since the upper portion of the resist (portion higher than the narrowed part) is detached during the development and the detached portion reattaches on the resist. Such disturbance of the shape and dimensions of the resist pattern has an adverse effect on the pattern shape of the underlying film (intermediate film, bottom film) after the etching using the resist pattern as a mask. The pattern shape of the underlying film (intermediate film, bottom film) has an influence on the shape of device pattern formed by processing using the underlying film as a mask. Therefore, the narrowed part CD value works as a criteria value (index value) for estimating the influence of the resist pattern on the shape of device pattern. Concretely, when the narrowed part CD value is smaller than a certain value (threshold), it may be estimated that the resist pattern has an adverse effect on the shape of device pattern (etching characteristics).

[Step S3]

The narrowed part CD value obtained in step S3 is determined whether it is equal to the predetermined value (threshold value) or higher under the exposure conditions that the CD value of the resist pattern is to be a designed value (the exposure conditions that the CD dimension accuracy of the resist pattern is to be secured), for example, the exposure conditions that a bottom dimension of the resist pattern is to be 59 nm. This designed value is appropriately determined depending on a mechanical strength or aspect ratio of the resist, developer, or development conditions.

[Step S4]

When the narrowed part CD value is equal to the predetermined value or higher as a result of the determination in step S3, it is determined that the resist stack designed in step S2 satisfies the required anti-reflection characteristic, CD accuracy and etching characteristic at the same time, and the exposure is performed under the exposure conditions designed in step S1. The target for the exposure is the stack in the resist stack designed in step S2.

[Step S5]

thereafter, the well-known process flows, such as forming a resist pattern by developing the exposed resist, then forming a device pattern by etching a substrate to be processed using a mask which is obtained by etching a remaining portion of the resist pattern using the resist pattern as a mask are followed.

When the top layer of the substrate is a polycrystalline silicon film or a metal film, a fine electrode pattern or a wiring pattern is formed as the device pattern. In addition, when the top layer of the substrate is an insulating film, a fine contact hole or gate insulating film is formed as the device pattern.

In addition, when the top layer of the substrate is a semiconductor substrate, a fine isolation trench (STI) is formed as the device pattern.

[Step S6]

On the other hand, when the narrowed part CD value is less the predetermined value as a result of the determination in step S3, the procedure goes to step S6. In the step S6, the two-dimensional illumination shape, which is one of the exposure conditions of a exposure apparatus, is corrected based on the information of pattern species (shape, dimensions) required for device pattern fabrication such that the narrowed part CD value becomes equal to or lager than the predetermined value under the exposure conditions that make the resist pattern CD value as desired (the exposure conditions that the CD dimension accuracy of the resist pattern is to be secured). At this time, the changing of two-dimensional illumination shape may cause a reduction of CD accuracy of a specific pattern in the device pattern or a dimensional shift between a dense area where the period of patterns is small and an isolated area where the period of patterns is high, then it is therefore desired to determine amount of the changing of two-dimensional shape of light source such that the adverse effects are to be sufficiently small. The changing of the two-dimensional shape of light source is performed by changing at least one of illumination shape such as a double pole illumination or quadruple pole illumination, σ value of the double pole illumination or the quadruple pole illumination, and brightness balance of the double pole illumination or the quadruple pole illumination. The designing of the illumination shape is carried out by using a simulation model of an aerial image which can predict the state of interference of light on the substrate at high speed.

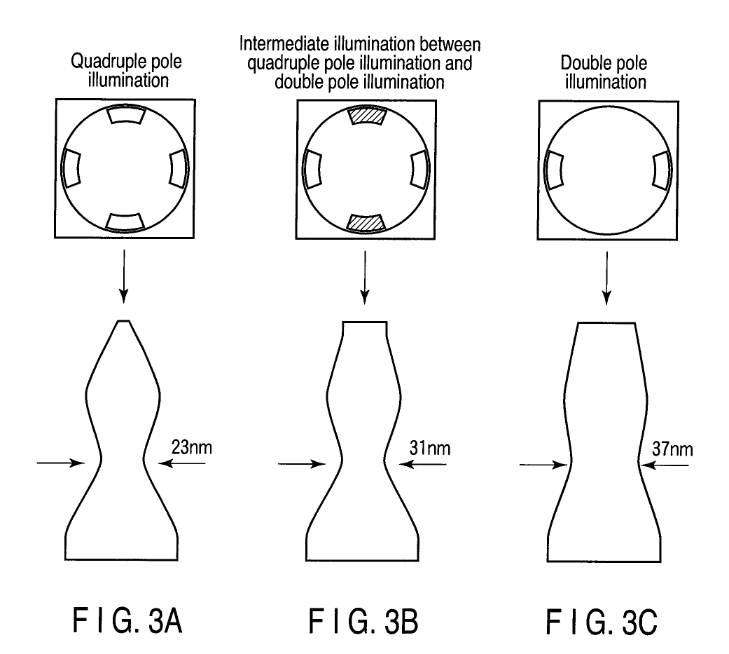

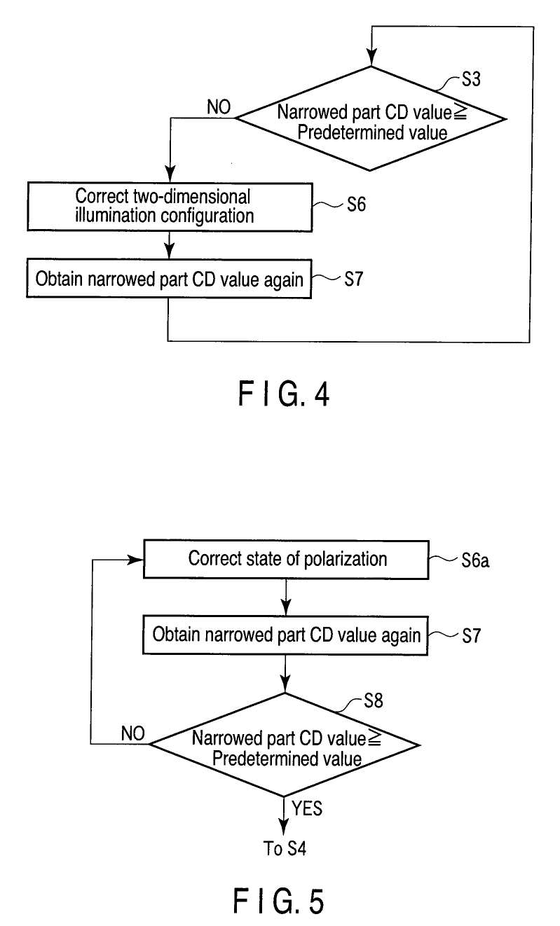

FIGS. 3A to 3C illustrate an example of relationship between secondary light source shape and cross-sectional shape of resist pattern (narrowed part CD value). As shown in FIG. 4, it can be seen that the changing of the secondary light source shape causes changing of the cross-sectional shape, and the narrowed part CD value varied. In the order of FIG. 3A, FIG. 3B and FIG. 3C, the narrowing is further reduced, and the narrowed part CD value is further increased.

That is, according to the study of the present inventors, it becomes apparent that the narrowed part CD value is controlled by the secondary light source shape and when the secondary light source shape is appropriately set, the cross-sectional shape of the resist pattern is stabilized without changing the etching characteristics of the resist stack, and the semiconductor device pattern is appropriately formed. In addition, as the cross-sectional shape of the resist pattern is stabilized without making changes to the resist stack, the time required to start up the semiconductor process is reduced.

The reason why the two-dimensional illumination shape can control the narrowed part CD value is that the intensity of light reflected from a bottom surface of the resist changes when the incidence angle of the light onto the bottom surface of the resist changes.

The bottom dimension of the resist pattern is 59 nm in each of FIGS. 3A, 3B and 3C. The bottom dimension can be controlled by exposure conditions (e.g., exposure).

[Step S7]

The narrowed part CD value is obtained again by using exposure conditions which is obtained by modifying (redesigning) the exposure conditions designed in step S1 by replacing the two-dimensional illumination shape in the exposure conditions with the two-dimensional illumination shape corrected in step S6.

[Step S8]

As in step S3, a determination is made as to whether or not the narrowed part CD value obtained in step S7 is equal to or larger than the predetermined value.

If the determination in step S8 is that the narrowed part CD value is equal to or larger than the predetermined value (YES), then the procedure goes to step S4. On the other hand, if the determination is that the narrowed part CD value is less than the predetermined value, then steps S6, S7 and S8 are repeated until the narrowed part CD value becomes equal to or larger than the predetermined value. The process may be aborted when the determination in step S8 is NO even if steps S6, S7 and S8 are repeated a predetermined number of times.

As shown in FIG. 4, a method (algorithm) may be used in which the determining in step S8 and the determining in step S3 are performed as one common determining.

In conventional techniques, there may arise a problem that the underlying film (the intermediate film, the bottom film) in the resist stack cannot suppress reflected light because of restrictions on its materials. There is a method to suppress reflected light by adding an adjust film between the intermediate film and the resist or between the bottom film and the intermediate film, however the addition of the adjust film results in a problem of increasing the manufacturing cost.

However, according to the present embodiment, there arise no problems of the conventional techniques associated with changing of the resist stack (material change of the underlying film, structural change by the addition of the adjust film, etc.) because the narrowed part CD value is controlled by the two-dimensional shape of light sources in the exposure apparatus. Therefore, according to the present embodiment, it becomes possible to implement a method of manufacturing a semiconductor device using a resist stack which can reduce the time period required to start up the semiconductor process.

Hereinafter, other embodiments will be described. In the remaining drawings, corresponding parts to those in the diagrams explained so far are designated by like reference characters and detailed descriptions thereof are omitted.

### Second Embodiment

FIG. 5 is a flowchart illustrating a method for manufacturing a semiconductor device according to a second embodiment.

The second embodiment is different from the first embodiment in that, if the determination in step S3 is that the narrowed part CD value is less than the predetermined value, the procedure goes to step S6a, then the state of polarization (the degree of polarization) of the exposure light, which is one of the exposure conditions of the exposure apparatus, is corrected such that the narrowed part CD value becomes equal to or lager than the predetermined value under the exposure conditions that make the resist pattern CD value as desired (the exposure conditions that the CD dimension accuracy of the resist pattern is to be secured).

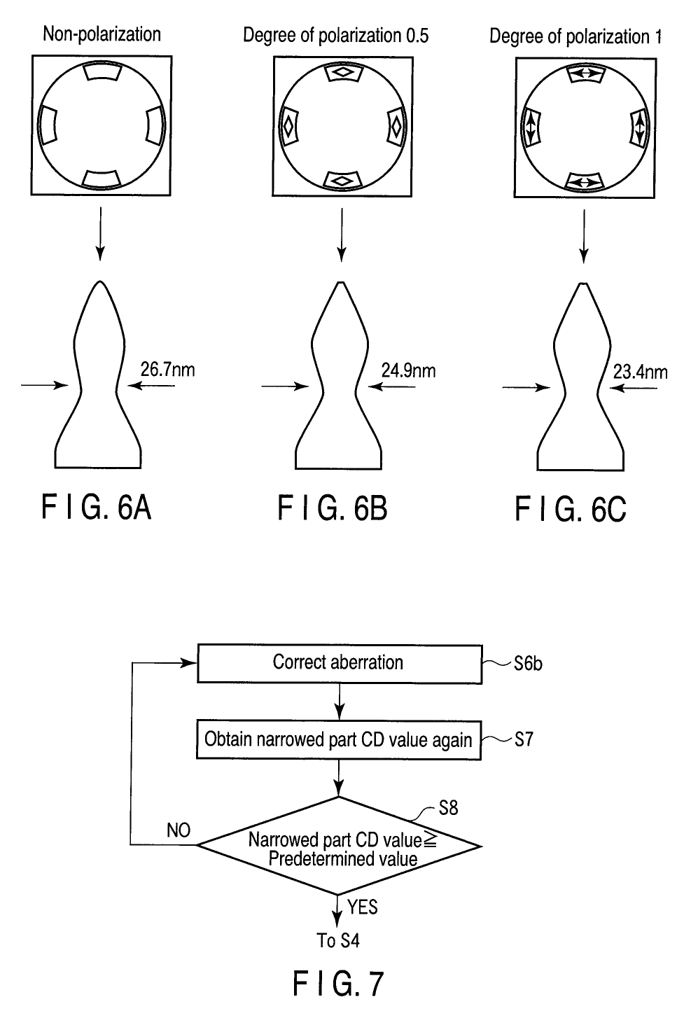

In FIGS. 6A, 6B and 6C, there is shown the relationship between the state of polarization (the degree of polarization) of exposure light and the cross-sectional shape (the narrowed part CD value) of the resist pattern. As show in FIGS. 6A, 6B and 6C, it can be seen that, when the degree of polarization changes, the cross-sectional shape of the resist pattern and the narrowed part CD value change. In the order of FIG. 6C, FIG. 6B and FIG. 6A, that is, as the degree of polarization decreases the narrowing is further reduced, and the narrowed part CD value is further increased.

That is, according to the study of the present inventors, it becomes apparent that the narrowed part CD value is controlled by the state of polarization (the degree of polarization) and when the degree of polarization is appropriately set, the cross-sectional shape of the resist pattern is stabilized without changing the etching characteristics of the resist stack, and the semiconductor device pattern is appropriately formed. In addition, as the cross-sectional shape of the resist pattern is stabilized without making changes to the resist stack, the time required to start up the semiconductor process is reduced.

The reason why the degree of polarization can control the narrowed part CD value is that the intensity of light reflected from a bottom surface of the resist changes when the degree of polarization of the light onto the bottom surface of the resist changes.

In general, p polarized light in which an oscillating direction of electric vector is parallel to a incident plane has smaller reflectance than s polarized light in which the oscillating direction of electric vector is perpendicular to the incident plane. Therefore, the change that the component of the p polarized light is increased is effective to suppress the narrowing of the cross-sectional shape of the resist.

The bottom dimension of the resist pattern is 59 nm in each of FIGS. 3A, 3B and 3C. The bottom dimension can be controlled by exposure conditions (e.g., exposure (taking into account the diffusion of acid)).

As in the case of the first embodiment, a method (algorithm) may be used in which the determination in step S3 is incorporated into the determination in step S8.

### Third Embodiment

FIG. 7 is a flowchart illustrating a method for manufacture of a semiconductor device according to the present embodiment.

The present embodiment is different from the first embodiment in that the narrowed part CD value is controlled by aberration of the projection lens.

In the present embodiment, if the determination in step S3 is that the narrowed part CD value is less than the predetermined value, the procedure goes to step S6a, then the aberration of the projection lens, which is one of the exposure conditions of the exposure apparatus, is corrected such that the narrowed part CD value becomes equal to or lager than the predetermined value under the exposure conditions that make the resist pattern CD value as desired (the exposure conditions that the CD dimension accuracy of the resist pattern is to be secured). Specifically, the spherical aberration is corrected.

The spherical aberration of the projection lens is a quantity that represents an error of image formation of the projection lens. If the spherical aberration exists, the phase of light is varied according to the angle of incident light. As a result, the height of the narrowed part varies according to the angle of incident light. The exposure light has a certain range of angles of incident light. Therefore, relating to the light having different incident angles, the position of narrowed part generated by the image formation can be made uniform or varied according to the spherical aberration.

That is, the narrowed part CD value is controlled by the aberration and when the aberration is appropriately set, the cross-sectional shape of the resist pattern is stabilized without changing the etching characteristics of the resist stack, and the semiconductor device pattern is appropriately formed. In addition, as the cross-sectional shape of the resist pattern is stabilized without making changes to the resist stack, the time required to start up the semiconductor process is reduced.

As in the case of the first embodiment, a method (algorithm) may be used in which the determination in step S3 is incorporated into the determination in step S8.

### Fourth Embodiment

In the first, second and third embodiments described above, the narrowed part CD value is controlled by one of the two-dimensional shape of light source, the state of polarization of exposure light, and the aberration of the projection lens as the exposure conditions, however it does not matter controlling the narrowed part CD value by two or more of exposure conditions in the above four exposure conditions. It becomes possible to stabilize the cross-sectional shape of the resist patter more effectively by controlling the narrowed part CD value using two or more of the exposure conditions.

### Fifth Embodiment

In the first to fourth embodiments described above, the narrowed part CD value is used as the criteria value. criteria values besides the narrowed part CD value are also available, which includes the bottom dimension of the resist pattern (dimension relating to the width of resist pattern), the side-wall angle of the resist pattern (the shape of resist pattern (the angle between the side and the base of a trapezoid when the cross-sectional shape of the resist pattern is approximated by trapezoid), the reduction of thickness of the resist pattern (reduced amount of height of the resist pattern from a predetermined value), the exposure latitude (EL) required for finishing a pattern to be formed in the resist or a film to be processed such that the pattern have allowable dimensions, the depth of focus (DOF), or the distribution of intensity of exposure light on the resist. In addition, the plurality of criteria values selected from the above mentioned criteria values may be used in a manner that the plurality of criteria values have the predetermined value at the same time. Thereby, the cross-sectional shape of the resist pattern can be stabilized more effectively.

### Sixth Embodiment

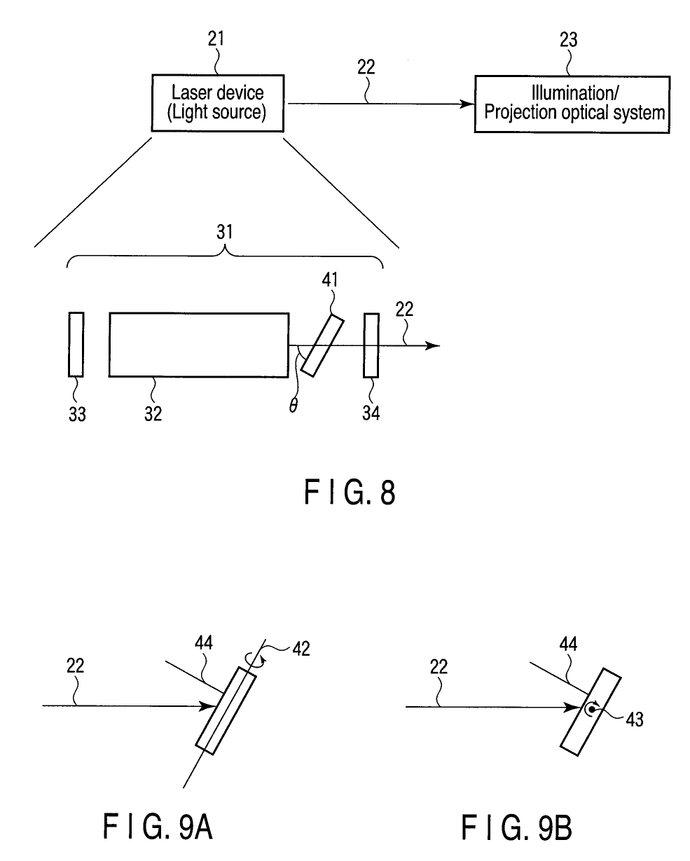

FIG. 8 is a schematic diagram of an exposure apparatus according to a sixth embodiment.

The exposure apparatus of the present embodiment comprises a laser device (exposure light source) 21 which is capable of controlling the state of polarization of emitted laser light 22, and an illumination/projection optical system 23 configured to illuminate a mask substrate (reticle) with laser light 22 from the laser device 21 and configured to project a pattern of the mask substrate (reticle) onto a substrate to be processed.

The laser device 21 comprises a resonator 31 (32, 33, 34) and a polarizer 41 which is provided in the optical path in the resonator and capable of controlling its attitude. The polarizer 41 is comprises parallel flat plates which are transparent to the wavelength of the laser light 22. The incident angle θ of the laser light 22 to the polarizer 41 (parallel flat plates) is configured to be set at Brewster angle. When the incident angle θ is set at Brewster angle, the laser light 22 will not contain p polarized light. The polarizer 41 may be detachable.

The degree of polarization of the laser light 22 can be changed by changing the attitude of the polarizer 41. Even if the incident angle θ is set at Brewster angle, the incident angle θ can be displaced from Brewster angle by changing the attitude of the polarizer 41.

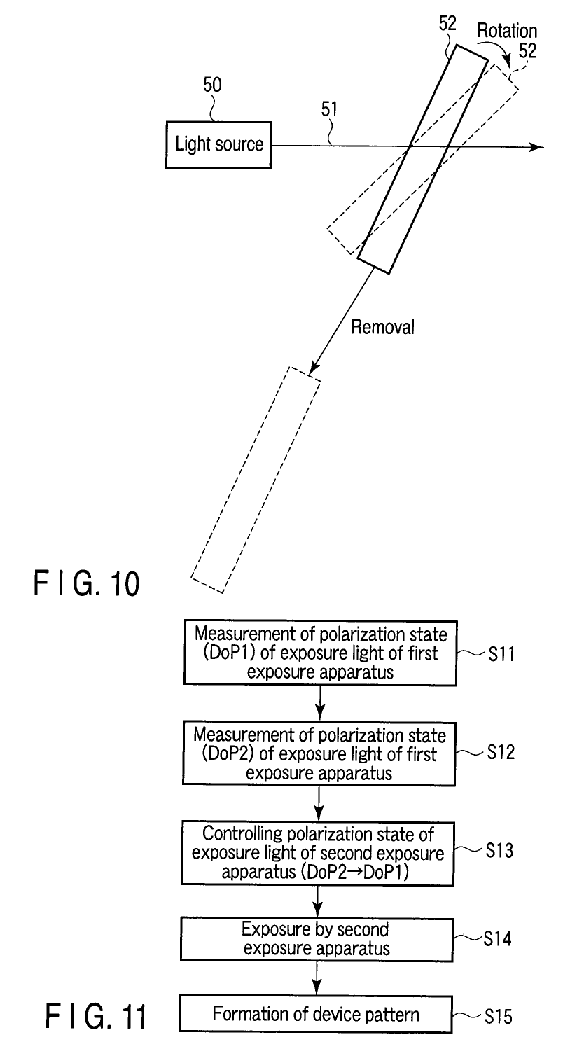

The attitude control of the polarizer 41 can be carried out by changing a rotation angle with respect to a rotation axis 42, a rotation angle with respect to a rotation axis 43, or both rotation angle, as shown in FIGS. 9A and 9B. The rotation axis 42 is included in a incident plane (not shown) of the laser light 22 (parallel to the drawing) and is perpendicular to a normal line 44 of the polarizer 41 (parallel flat plates). The rotation axis 43 is orthogonal to the incident plane of (not shown) the laser light 22 (perpendicular to the drawing) and is perpendicular to the normal line 44 of the polarizer 41 (parallel flat plates).

The resonator 31 comprises a laser chamber 32 in which a laser medium is sealed and mirrors 33 and 34 which are provided on the both ends of the laser chamber 32. The mirror 34 is a semitransparent mirror and provided on a side from which the laser light 22 emits. Light generated in the laser chamber 32 travels back and forth between the two mirrors 33 and 34 several times, thereafter a laser light 22 is emitted toward the illumination/projection optical system 23 via the polarizer 41. The laser light 22 enters the illumination optical system of the illumination/projection optical system 23.

According to the present embodiment, the degree of polarization of the laser light 22 is controlled by the attitude (angle of rotation) of the resonator 41, thus allowing the state of polarization of light on a surface to be irradiated of the mask substrate is maintained in the desired condition.

The exposure apparatus of the present embodiment can be used to implement the semiconductor device manufacturing method which correct the state of polarization (the degree of polarization) such that the narrowed part CD value becomes equal to or larger than the predetermined value as in the case of the second embodiment for instance.

### Seventh Embodiment

In the sixth embodiment, the unit (polarizer) configured to control the state of polarization of light is provided inside the laser light source. In contrast, in the present embodiment, a unit (phase plate) configured to control the state of polarization of light is provided outside the laser light source.

FIG. 10 is a schematic diagram of an exposure apparatus according to the present embodiment. Light (laser light) 51 emitted from a light source 50 is irradiated on a phase plate 52 placed in the optical path inside the exposure apparatus. The phase plate 52 has a function of changing the state of polarization (linear polarization, circular polarization, elliptic polarization, etc.) of light 51.

The state of polarization of light 51 (outgoing light) can be controlled by mounting or removing the phase plate 52, or controlling its attitude (rotation). The phase plate 52 is designed such that it is mounted or removed, or its attitude is controlled by well-known mechanism.

According to the present embodiment, the state of polarization of the light 51 can be controlled by mounting or removing the phase plate 52, or controlling its attitude (rotation), thus allowing the state of polarization of light on a surface to be irradiated of the mask substrate is maintained in the desired condition.

The exposure apparatus of the present embodiment can be used to implement the second embodiment for instance.

### Eighth Embodiment

Conventionally, in manufacturing semiconductor devices using optical lithography techniques, projection and exposure systems is used, which project a circuit pattern drawn on a photomask onto a wafer or the like via the projection optical system and the circuit pattern is transferred on wafer or the like.

In recent years, to meet the demand for fine patterning of semiconductor devices, an exposure apparatus has been developed which is adapted to expose a pattern which is in size half the wavelength of exposure light or less. Such enhanced resolution is generally achieved by shortening the wavelength of exposure light and increasing the numerical aperture (NA) of the projection optical system. Increasing the NA of the projection optical system means that the angle between a normal line of the image surface and a propagation direction of the incident light becomes larger.

In the enhanced NA image formation, the polarization of exposure light is a problem. For example, in a case of exposure for a line-and-space (LS) pattern which is a repetition of line and space, there is a following problem.

The LS pattern is formed by interference of two light flux of plane waves. The incident plane is a plane including incident direction vectors of the two light flux, the polarization that electrical vector of light perpendicular to the incident plane is s polarization, the polarization that electrical vector of light parallel to the incident plane is p polarization (Jpn. Pat. Appln. KOKAI Publication No. 2007-258575).

When the angle between the incident direction vectors of the two light fluxes is close to 90 degrees, as the p polarization interferes, the light intensity corresponding to the LS pattern is formed on the image plane. On the other hand, in the case of s polarization, as the oscillation direction of the electric vector is nearly perpendicular, the effect of the interference is weaken so that the distribution of light intensity becomes nearly constant, and the light intensity corresponding to the LS pattern is not formed on the image plane.

When the s polarization and the p polarization are mixed, a distribution of light intensity, which has a lower contrast than the distribution of light intensity in the case of s polarization only, is formed on the image plane. If the ratio of p polarization is high, the contrast of the distribution of light intensity on the image plane is lowered, which makes it difficult to form the LS pattern. Therefore, in general, the exposure is performed by using the s polarized light at the time of forming a fine line and space pattern of 45 nm half pitch for instance.

Furthermore, a very small difference in the degree of polarization of exposure light between exposure apparatuses affects the image performance of coarse and dense patterns and produces a coarse and dense dimensional variation between the exposure apparatuses. The same photomask cannot be used for exposure apparatuses between which the coarse and dense dimensional variation is present. In other words, each of the apparatuses needs a photomask subjected to a different optical proximity effect correction (OPC) process. From the standpoint of the lead time of mass production of semiconductor devices and the calculation cost for OPC, it is difficult to accept the application of different OPC process for each the exposure apparatus.

In recent years, in order to form fine semiconductor device patterns, an exposure apparatus using an excimer laser as a light source is generally used (e.g., Jpn. Pat. Appln. KOKAI Publication No. 2003-347627).

The excimer laser is structured to emit polarized light. When the above mentioned exposure utilizing the polarization is performed, an error of degree of polarization of the excimer laser affects the image characteristics. In general, since the error of degree of polarization differs between the exposure apparatuses, there will also arise the aforementioned problems of the lead time of mass production of semiconductor devices and the calculation cost for OPC.

The present embodiment is directed to a method for manufacture of a semiconductor device which can solve the problems which arise from the difference of error of the degree of polarization between exposure apparatuses, which will be described below.

FIG. 11 is a flowchart illustrating a method for manufacture of a semiconductor device according to a ninth embodiment.

[Step S11]

The state of polarization (degree of polarization) on a substrate to be processed in a first exposure apparatus using a laser light as an exposure light is measured in the well-known way. The measurement result is denoted by DoP1.

[Step S12]

The state of polarization (degree of polarization) on a substrate to be processed in a second exposure apparatus using a laser light as an exposure light is measured in the well-known way. The measurement result is denoted by DoP2. The difference in configuration between the first and second exposure apparatuses lies in whether the state of polarization of laser light can be controlled or not, and other configuration is the same.

Here, it is assumed that the second exposure apparatus is capable of controlling the state of polarization of exposure light. An example of such the second exposure apparatus is the one described in the seventh or eighth embodiment. However, the second exposure apparatus is not restricted to the examples.

[Step S13]

On the basis of the measurements (DoP1 and DoP2) in steps S11 and S12, the state of polarization of laser light in the second exposure apparatus is controlled so as to come close to that in the first exposure apparatus (DoP2→DoP1). It therefore becomes possible to bring the image characteristic on the resist on the substrate in the second exposure apparatus close to that in the first exposure apparatus. The image characteristic is, for example, the dimensional difference between a first pattern and a second pattern different in periodicity from the first pattern, the exposure latitude of the first pattern, or the distribution of light intensity.

[Step S14]

Using the second exposure apparatus whose state of the polarization of laser light is controlled in step S13, the resist on the substrate to be processed is exposed.

[Step S15]

A device pattern is formed through the well-known processes which include a step of developing the exposed resist to form a resist pattern and a step of etching the substrate to be processed using the mask pattern as a mask.

According to the present embodiment, the lead time until the exposure apparatuses are put into operation can be reduced and the productivity can be improved because the image characteristic can be made common to the first and second exposure apparatuses and the masks subjected to the same OPC process can be used.

It does not matter that both the first and second exposure apparatuses are capable of controlling the state of polarization of laser light. In this case, for example, the state of polarization of laser light (s polarization and p polarization) in the first exposure apparatus is controlled so that a desired image characteristic can be obtained (for example, a distribution of light intensity corresponding to an LS pattern is to be formed on the image plane), moreover, the state of polarization of laser light in the second exposure apparatus is controlled so that the above desired image characteristic can be obtained, and it therefore becomes possible to form a fine device pattern with high accuracy.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device comprising:
designing a resist structure to be formed on a substrate, the resist structure comprising a film having antireflection function for exposure light and a resist provide on the film;
designing an exposure condition of the resist such that a resist pattern is finished as designed, the resist pattern being obtained by exposing and developing the resist;
obtaining criteria value for estimating influence of a resist pattern upon a dimension or shape of a device pattern, the resist pattern being obtained by exposing the resist under the designed exposure condition and developing the exposed resist, the device pattern being obtained by etching the resist structure by using the resist pattern as a mask;
determining whether the designed exposure condition is acceptable or not based on the criteria value; and
redesigning the exposure condition of the resist without changing the designed resist structure when the designed exposure condition is determined not acceptable.

2. The method according to claim 1,
further comprising forming a resist pattern by exposing the resist under the designed exposure condition and etching the substrate by using the resist pattern as a mask when the designed exposure condition is determined acceptable.

3. The method according to claim 1,
further comprising determining whether the redesigned exposure condition is acceptable or not.

4. The method according to claim 3,
further comprising forming a resist pattern by exposing the resist under the redesigned exposure condition and etching the substrate using the resist pattern as a mask when the redesigned exposure condition is determined acceptable.

5. The method according to claim 1,
wherein the exposure condition includes a secondary light source shape of an exposure apparatus, polarization state of an exposure light and an aberration of a projector lens of an exposure apparatus,
the redesigning the exposure condition of the resist includes redesigning at least one of the secondary light source shape, the polarization state and the aberration.

6. The method according to claim 1,
wherein the criteria value is dimension relating to width of the resist pattern, sidewall angle of the resist pattern, reduction of the resist pattern, exposure latitude, focus latitude or light distribution of the exposure light on the resist.

7. The method according to claim 1,
wherein the dimension relating to the width of the resist pattern is dimension of narrowed part in a height direction of the resist pattern, bottom dimension of the resist pattern, dimension at a position of narrowed part of the resist pattern at a specific height of the resist pattern, or dimension at a position of narrowed part of the resist pattern having the smallest dimension in width.

8. The method according to claim 1,
wherein the dimension relating to the width of the resist pattern is obtained based on a resist pattern predicted by calculation.

9. The method according to claim 1,
wherein the dimension relating to the width of the resist pattern is obtained by measuring a resist pattern actually formed.

10. The method according to claim 1,
wherein the resist structure further comprises a protective film for preventing a surface of the resist from liquid.

11. The method according to claim 1,
wherein the redesigning the exposure condition of the resist includes exposing the resist by using an exposure apparatus configured to control a state of polarization of the exposure light in a case of redesigning at least the state of polarization of the exposure light.

12. The method according to claim 11,
wherein the exposure apparatus comprises a laser device which includes a laser light source configured to emit a laser light, a control unit provide inside the laser light source and configured to control a state of polarization of the laser light.

13. The method according to claim 12,
wherein the control unit comprises a polarizer.

14. The method according to claim 11,
wherein the exposure apparatus comprises a laser device which includes a laser light source configured to emit a laser light, a control unit provide outside the laser light source and configured to control a state of polarization of the laser light.

15. The method according to claim 14,
wherein the control unit comprises a phase plate.
